(19) United States
(12) Patent Application Publication
(10) Pub. No.: US 2015/0204944 A1
(43) Pub. Date: Jul. 23, 2015

(54) PROGRAMMABLE LOGIC DEVICE AND VERIFICATION METHOD THEREFOR

(71) Applicant: KABUSHIKI KAISHA TOSHIBA, Minato-ku, Tokyo (JP)

(72) Inventors: Shuji Hamada, Sagamihara (JP); Yukitaka Yoshida, Fuchu (JP); Atsushi Kojima, Nishitokyo (JP)

(73) Assignee: KABUSHIKI KAISHA TOSHIBA, Minato-ku, Tokyo (JP)

(21) Appl. No.: 14/425,144

(22) PCT Filed: Sep. 11, 2013
(86) PCT No.: PCT/JP2013/074534

§ 371 Date: Mar. 2, 2015

(30) Foreign Application Priority Data
Sep. 14, 2012 (JP) 2012-203486

(51) Int. Cl. G01R 31/3183; G01R 31/3177; G01R 31/3185; H03K 19/177

(52) U.S. Cl. CPC G01R 31/3183; H03K 19/177; G01R 31/3177; G01R 31/318519

(57) ABSTRACT

Provided are: a programmable logic device capable of efficiently verifying whether an internal status of each sequential circuit makes transition equivalent to that of a logic program written in a hardware description language (HDL); and a verification method for the programmable logic device.

A programmable logic device 10 includes: an I/O unit 17 that inputs and outputs digital signals to and from implemented logic elements and an outside; generation units 12 (12a, 12b, 12c, 12d) that acquire internal status signals of sequential circuits included in respective corresponding divided regions 11 (11a, 11b, 11c, 11d) to each of which a group of the logic elements is assigned, and generate status information 13 (13a, 13b, 13c, 13d) for each divided region 11 as a unit; and a selective output unit 14 that acquires the status information 13 from each divided region 11 and selectively outputs the status information 13 to the outside.

### TECHNICAL FIELD

An embodiment of the present invention relates to a programmable logic device having hardware on which a logic circuit is implemented according to a hardware description language made of text data and to a verification method for the programmable logic device.

### BACKGROUND ART

In general, a field-programmable gate array (FPGA), which is, for example, implemented on a safety system control board in a nuclear power plant, has hardware on which a larger-scale logic circuit is implemented, among devices categorized in a programmable logic device (PLD).

A process of implementing a logic circuit onto hardware according to a hardware description language (HDL) is performed while a conversion tool that is a black box is used one or more times.

Accordingly, a logic program written in the hardware description language (HDL) and a logic operation of a FPGA implemented on the basis of the logic program need to be equivalent to each other.

A known technique for verifying whether a logic program written in the HDL and a logic operation of a FPGA are equivalent to each other involves: inputting a common test pattern to each of the logic program and the FPGA; and checking whether the output results obtained from the two are coincident with each other (for example, Patent Documents 1 and 2).

### PRIOR ART DOCUMENTS

### Patent Documents

Patent Document 1: Japanese Patent Laid-Open No. 2008-158696

Patent Document 2: International Publication No. WO 2008/020513

### SUMMARY OF THE INVENTION

### Problems to be Solved by the Invention

Unfortunately, in the case where a logic circuit includes sequential circuits such as flip-flops, it is difficult to verify the equivalence in consideration of an internal status of each of the plurality of flip-flops.

The present invention, which has been made in view of the above-mentioned circumstances, has an object to provide a programmable logic device capable of efficiently verifying whether an internal status of each sequential circuit makes transition equivalent to that of a logic program written in a hardware description language (HDL) and provide a verification method for the programmable logic device.

### BRIEF DESCRIPTION OF THE DRAWINGS

FIG. 1 is a block diagram of a programmable logic device according to a first embodiment of the present invention.

FIG. 2 is a block diagram of a programmable logic device according to a second embodiment of the present invention.

FIG. 3 is a block diagram of a programmable logic device according to a third embodiment of the present invention.

FIG. 4 is a flow chart showing a general process of manufacturing the programmable logic device.

FIG. 5 is a flow chart showing a process of verifying the programmable logic device according to each embodiment.

### DESCRIPTION OF EMBODIMENTS

### First Embodiment

Hereinafter, an embodiment of the present invention is described with reference to the attached drawings.

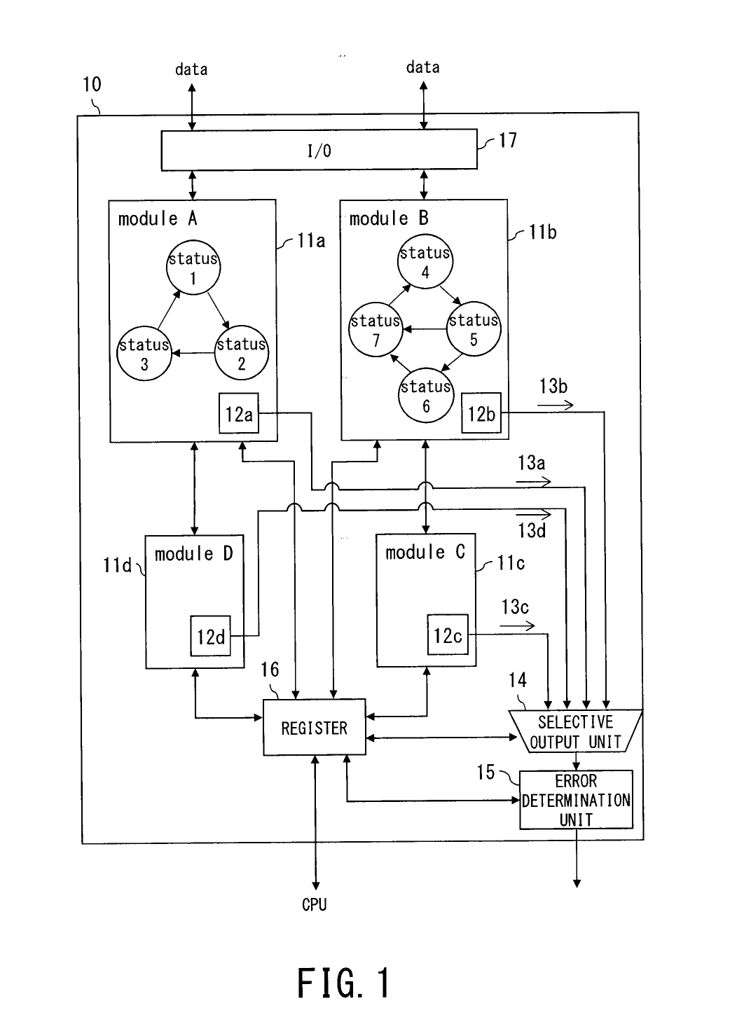

As illustrated in FIG. 1, a programmable logic device 10 (hereinafter, also simply referred to as FPGA) according to a first embodiment includes: an I/O unit 17 that inputs and outputs digital signals to and from implemented logic elements (not illustrated) and an outside; generation units 12 (12a, 12b, 12c, 12d) that acquire internal status signals of sequential circuits included in respective corresponding divided regions 11 (11a, 11b, 11c, 11d) to each of which a group of the logic elements is assigned, and generate status information 13 (13a, 13b, 13c, 13d) for each divided region 11 as a unit; and a selective output unit 14 that acquires the status information 13 from each divided region 11 and selectively outputs the status information 13 to the outside.

The programmable logic device 10 further includes an error determination unit 15 in which patterns of the status information 13 possible for the divided region 11 are registered in advance, the error determination unit 15 outputting an error signal if status information 13 that is not coincident with any of the patterns is generated.

The FPGA is a LSI having a basic structure in which: relatively small-scale programmable logic elements are arranged in a grid-like pattern; and a wiring route is provided between adjacent logic elements in a longitudinal direction and a transverse direction.

The logic elements can be connected in a given combination by a switch matrix provided to the wiring route.

The I/O unit 17, memory blocks, and other special functional logics are further implemented on the FPGA, and hence the FPGA does not require an external special functional LSI or IC, and a system of the FPGA can be achieved as one chip.

Hundreds to millions of logic elements are arranged on a commercially available FPGA. The logic elements are combined and connected on the basis of a hardware description language (HDL) that represents operation specifications of the FPGA on a text base, whereby a large-scale circuit is achieved.

The hardware description language (HDL) is written in a unit called module, each component is described as a module, and an entire system is configured by connecting such modules.

For this reason, in FPGA designing, a large-scale system can be efficiently developed by reusing modules described in the past and utilizing commercially available modules.

Each logic element is generally configured by combining a lookup table (LUT) for achieving a combinational logic with a flip-flop for achieving a sequential logic.

The LUT is a function for achieving an N-input/one-output truth table as a circuit. Specifically, with the use of a memory having an N-bit address, an output value is written into a storage element (SRAM), whereby a given N-input combinational logic is defined.

The flip-flop is used to obtain synchronous outputs of paired LUTs and configure a sequential circuit, for logic elements connected to each other.

Each divided region 11 (11a, 11b, 11c, 11d) is a region to which a group of the logic elements is assigned so as to correspond to a module that is a basic structure of the hardware description language (HDL). How to assign the logic elements is not particularly limited.

A plurality of logic elements configured as combinational circuits (for example, logic gates such as AND, OR, NOT, and XOR) and a plurality of logic elements configured as sequential circuits (for example, a flip-flop and a counter) are arranged in each divided region 11.

The “combinational circuit” here refers to a circuit whose output is uniquely determined by a combination of acquired inputs, and the “sequential circuit” here refers to a circuit whose output is determined by acquired inputs and its internal status.

The internal status of the sequential circuit can be taken out as an internal status signal via the wiring route in the FPGA.

The generation units 12 (12a, 12b, 12c, 12d) acquire the internal status signals of the sequential circuits included in the respective corresponding divided regions 11 (11a, 11b, 11c, 11d).

Assuming that the number of sequential circuits is n and that the number of internal statuses is p, the number of combination patterns of the internal status signals acquired by each generation unit 12 is estimated to be pⁿ at a maximum.

In reality, the number of internal status patterns possible for all the sequential circuits included in the divided region 11 described in a unit of module is significantly smaller than the maximally estimated number.

On the basis of the acquired internal status signals of the plurality of sequential circuits, the generation units 12 (12a, 12b, 12c, 12d) generate the status information 13 (13a, 13b, 13c, 13d) indicating the internal status, for each corresponding divided region 11 (11a, 11b, 11c, 11d) as a unit, and output the status information 13 to the selective output unit 14.

In FIG. 1, three internal status patterns (status 1, status 2, status 3) are possible for the divided region 11a, and the number of types of the corresponding status information 13a is three. Four internal status patterns (status 4, status 5, status 6, status 7) are possible for the divided region 11b, and the number of types of the corresponding status information 13b is four.

Similarly, a plurality of internal status patterns are possible for the divided regions 11c and 11d, and illustration thereof is omitted.

Test patterns for causing the internal status of the divided region 11 to be verified to make transition as indicated by arrows are continuously inputted to the I/O unit 17. Then, the generation unit 12 outputs the type of the corresponding status information 13 along with the transition of the internal status.

It is desirable that the status information 13 be expressed by the number of bits corresponding to the number of types of the status information 13 possible for the divided region 11. That is, the illustrated status information 13a is expressed by three bits, and the illustrated status information 13b is expressed by four bits. This enables a high-speed response without causing a hazard in outputs.

The selective output unit 14 acquires the pieces of status information 13 (13a, 13b, 13c, 13d) in parallel from all the generation units 12 (12a, 12b, 12c, 12d) in the divided regions 11. Then, the selective output unit 14 selectively outputs the status information 13 in which the internal status of the divided region 11 to be verified is reflected, to the outside.

The selection operation of the selective output unit 14 is performed in response to a command that is received from an external CPU via a register 16, or is performed by setting a rotary switch (not illustrated).

Although it is conceivable to output all the pieces of the status information 13 (13a, 13b, 13c, 13d) from the FPGA to the outside, the number of unused pins available to output the status information 13 to the outside is limited.

Accordingly, the selective output unit 14 outputs only the status information 13 in which the internal status of the divided region 11 to be verified is reflected, to the outside, whereby the number of used pins can be reduced.

The patterns of the status information 13 possible for the divided region 11 according to a test pattern are registered in advance in the error determination unit 15. If status information 13 that is coincident with any of the patterns is inputted, the error determination unit 15 allows the status information 13 to pass therethrough, and outputs the status information 13 to the outside. If status information 13 that is not coincident with any of the patterns is inputted, the error determination unit 15 converts the status information 13 into an error signal, and outputs the error signal to the outside.

An installation position of the error determination unit 15 and the number thereof are not particularly limited. The error determination unit 15 may be provided for each divided region 11 (11a, 11b, 11c, 11d).

The register 16 is used to set an operation mode and the like of each module in the FPGA and to read the internal status of each module from the outside, in response to external access from a CPU and the like. Accordingly, if the register 16 is accessed from the outside, each module in the FPGA can be individually controlled.

The error determination unit 15 may be configured as a device independent of the FPGA. In this case, the external error determination unit 15 is connected to the FPGA such that the external error determination unit 15 can receive the status information 13 from the selective output unit 14, and thus makes error determination.

### Second Embodiment

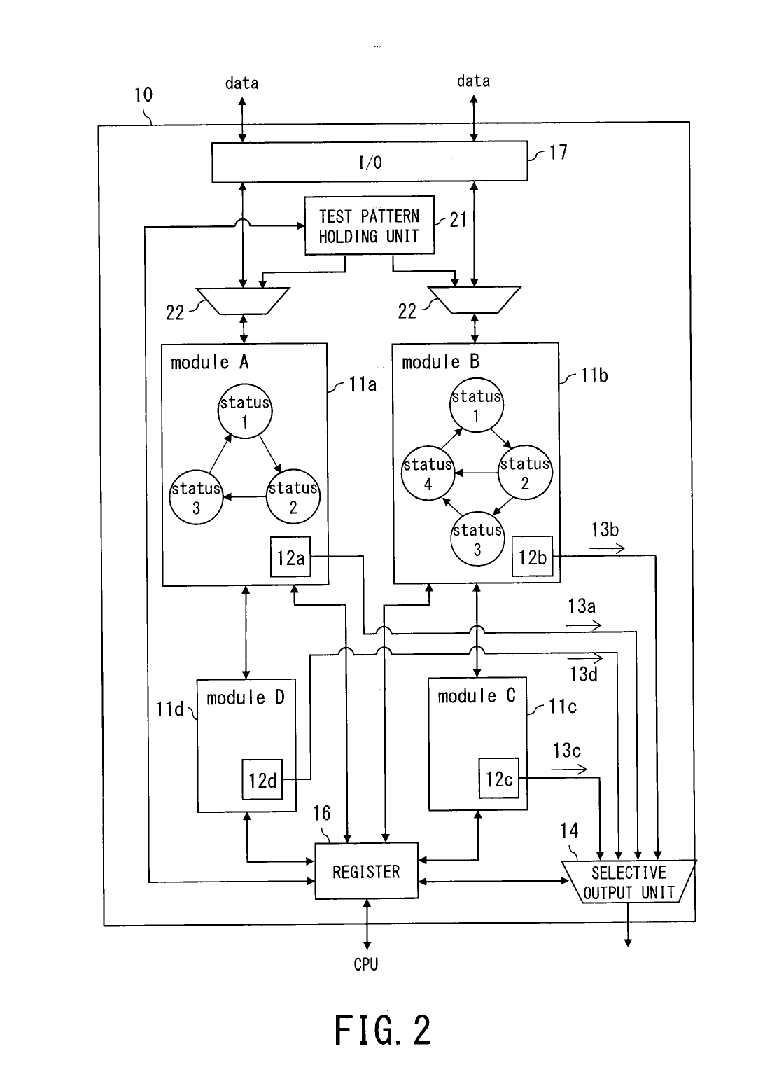

Next, a second embodiment of the present invention is described with reference to FIG. 2. In FIG. 2, portions having configurations or functions common to those in FIG. 1 are denoted by the same reference signs, and redundant description thereof is omitted.

As illustrated in FIG. 2, the programmable logic device 10 according to the second embodiment further includes a test pattern holding unit 21 that holds a test pattern of a digital signal to be inputted to an input terminal of the divided region 11.

The test pattern is set for each divided region 11 (11a, 11b, 11c, 11d) to be verified, and is held in the test pattern holding unit 21.

The test pattern is created using a simulator of the hardware description language such that transition is made in order to all the pieces of status information 13 that can be outputted from the divided region 11 to be verified.

The test pattern from the outside is sent from the I/O unit 17 via a switching unit 22 to be held by the holding unit 21, and the held test pattern is inputted to the input terminal of each divided region 11 via the switching unit 22.

In order to sequentially output different test patterns respectively corresponding to the divided regions 11 to be verified, an operation of the holding unit 21 is controlled by the register 16 so as to be synchronized with the selection operation of the selective output unit 14.

During a normal operation of the FPGA, the switching unit 22 connects the I/O unit 17 to the input terminal of each divided region 11, whereby data is inputted and outputted to and from the outside.

The error determination unit 15 may be connected to the selective output unit 14, whereby error determination can be made in order of the inputted test patterns.

### Third Embodiment

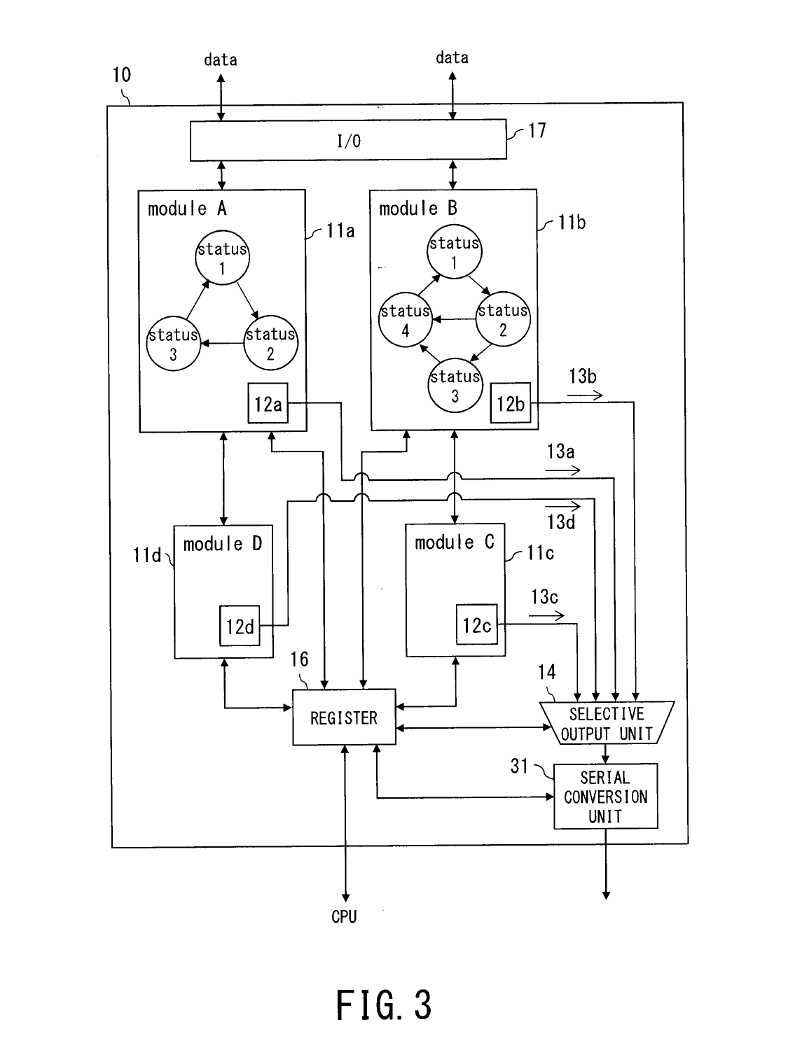

Next, a third embodiment of the present invention is described with reference to FIG. 3. In FIG. 3, portions having configurations or functions common to those in FIG. 1 are denoted by the same reference signs, and redundant description thereof is omitted.

As illustrated in FIG. 3, the programmable logic device 10 according to the third embodiment further includes a serial conversion unit 31 that outputs the status information 13 expressed by a plurality of bits one bit by one bit.

That is, the serial conversion unit 31 converts the status information 13 expressed by at least two bits into serial data, whereby the number of pins necessary to output data to the outside can be reduced to one.

The serial conversion unit 31 described above is configured by, for example, implementing a FIFO (first-in first-out) in a stage subsequent to the selective output unit 14, further implementing a write circuit for writing data into the FIFO, and further implementing a serial conversion circuit for serially outputting the data written in the FIFO.

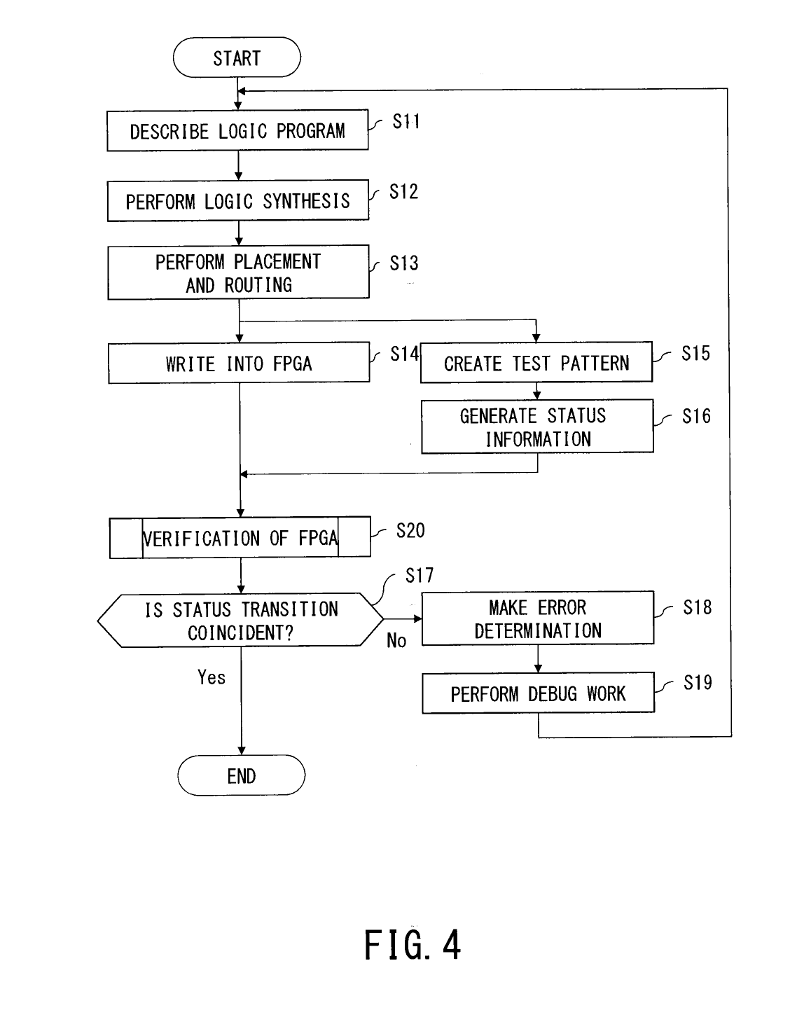

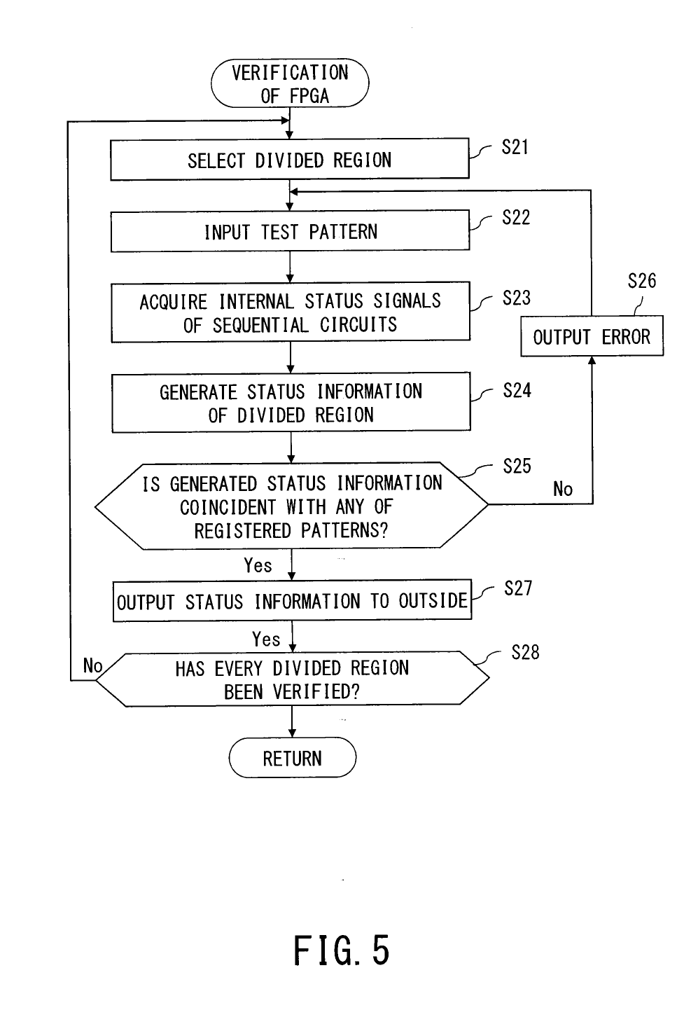

A flow chart of FIG. 4 shows a general process of manufacturing the programmable logic device, and a flow chart of FIG. 5 shows a process of verifying the programmable logic device according to each embodiment.

A programmer sets a description level to a register transfer level (RTL), and describes a logic program using the hardware description language (HDL) (S11).

Then, logic synthesis is performed for converting the logic program into circuit information (netlist) in a gate level such as AND and OR (S12), placement and routing are performed for assigning the converted circuit information to logic elements in the FPGA (S13), and a bit stream to be written into the FPGA is generated. The above-mentioned work is normally performed on a general-purpose computer.

Then, the general-purpose computer is connected to the FPGA, and the generated bit stream is transmitted, whereby a logic circuit is written into the FPGA (S14).

In parallel with this work or before or after this work, a test pattern is created on the general-purpose computer according to a simulation based on the logic program written in the hardware description language (S15), and status information that makes transition in the case where the test pattern is inputted to a module is generated (S16).

Equivalence of the FPGA is verified (S20 (FIG. 5)) on the basis of the acquired test pattern and the transition of the status information simulated by the input of the test pattern.

First, a divided region 11 to be verified in the FPGA (S21) is selected, status information patterns possible for the divided region 11 are registered, and a corresponding test pattern is inputted to the input terminal of the divided region 11 (S22).

Then, the generation unit 12 acquires internal status signals of sequential circuits included in the divided region 11 to be verified (S23), so that the status information 13 of the divided region 11 is generated (S24).

If the generated status information 13 is not coincident with any of the registered patterns (No in S25), it is determined that the logic program written in the HDL and the logic operation of the FPGA are not equivalent to each other, and an error is outputted (S26).

Meanwhile, if the generated status information 13 is coincident with any of the registered patterns (Yes in S25), the status information 13 is outputted to the outside, and the transition thereof is observed (S27).

Then, the flow of (S22) to (S27) is performed on every divided region 11, and the equivalence between the logic program written in the HDL and the logic operation of the FPGA is verified (S28).

Then, if the transition of the status information 13 outputted to the outside and the transition of the status information simulated from the logic program are coincident with each other (Yes in S17 of FIG. 4), it is determined that the logic program written in the HDL and the logic operation of the FPGA are equivalent to each other, and the verification process is ended.

Meanwhile, if the transition of the status information 13 outputted to the outside and the transition of the status information simulated from the logic program are not coincident with each other (No in S17), error determination is made (S18), and the process returns to (S11) for debug work (S19).

According to the programmable logic device of at least one embodiment described above, the transition of the status information is observed for each divided region as a unit to which a group of the logic elements is assigned, whereby it is more easily verified whether or not the logic operation thereof is equivalent to the logic program written in the hardware description language (HDL).

Although some embodiments of the present invention are described above, these embodiments are given as mere examples, and are not intended to limit the scope of the present invention. These embodiments can be carried out in other various modes, and various omissions, replacements, changes, and combinations are possible therefor within a range not departing from the gist of the present invention. These embodiments and modifications thereof are included in the scope and gist of the present invention, and are also included in the inventions described in CLAIMS and a range equivalent thereto.

1. A programmable logic device comprising:
an I/O unit that inputs and outputs digital signals to and from implemented logic elements and an outside;
generation units that acquire internal status signals of sequential circuits included in respective corresponding divided regions to each of which a group of the logic elements is assigned, and generate status information for each divided region as a unit; and
a selective output unit that acquires the status information from each divided region and selectively outputs the status information to the outside.

2. The programmable logic device according to claim 1, further comprising an error determination unit in which patterns of the status information possible for the divided region are registered in advance, the error determination unit outputting an error signal if status information that is not coincident with any of the patterns is generated.

3. The programmable logic device according to claim 1, wherein the status information is expressed by the number of bits corresponding to the number of types of the status information possible for the divided region.

4. The programmable logic device according to claim 1, further comprising a test pattern holding unit that holds a test pattern of the digital signal to be inputted to an input terminal of the divided region.

5. The programmable logic device according to claim 1, further comprising a serial conversion unit that outputs the status information expressed by a plurality of bits one bit by one bit.

6. A verification method for a programmable logic device, comprising the steps of:
acquiring a test pattern and status information that makes transition in response to an input of the test pattern, according to a simulation based on a logic program written in a hardware description language;
inputting the test pattern to an input terminal of the divided region in the programmable logic device according to claim 1;
outputting, to an outside, status information from the programmable logic device for each divided region as a unit; and
comparing transition information of the status information simulated from the logic program with transition information of the status information that is outputted to the outside from the programmable logic device.
